(19) United States
(12) Patent Application Publication
(10) Pub. No.: US 2026/0164599 A1
(43) Pub. Date: Jun. 11, 2026

(54) EXPANSION CARD

(71) Applicant: COOLER MASTER TECHNOLOGY INC., Taipei City (TW)

(72) Inventors: Ming-Chun HSU, Taipei City (TW); Chen-Chou KAO, Taipei City (TW)

(73) Assignee: COOLER MASTER TECHNOLOGY INC., Taipei City (TW)

(21) Appl. No.: 19/394,031

(22) Filed: Nov. 19, 2025

(30) Foreign Application Priority Data
Dec. 10, 2024 (TW) 113213583

(51) Int. Cl. H05K 7/20

(52) U.S. Cl. CPC H05K 7/20154; H05K 7/20336

(57) ABSTRACT

An expansion card can includes a first housing, a second housing coupled with the first housing to define an internal space, the second housing having at least one ventilation opening communicating with the internal space, a substrate disposed on the first housing and within the internal space, a heat dissipation device disposed on the substrate, and at least one fan disposed on the second housing and within the internal space, and located at the corresponding ventilation opening.

### RELATED APPLICATIONS

This US application claims priority to Taiwan Application No. 113213583, filed on Dec. 10, 2024, which is incorporated herein by reference in its entirety.

### TECHNICAL FIELD

The present disclosure is related to the field of expansion cards, in particular an expansion card with fans disposed on a housing.

### BACKGROUND

In computer systems, expansion cards are used for a variety of functions, including image processing, network interfaces, peripheral device interfaces, and data storage. Users can install expansion cards with necessary features in computer systems as much... To increase computer functionality. For example, users can install display adapters to meet increased image processing requirements.

Display adapters typically include heat dissipation devices and fans to dissipate heat from display chips contained within the display adapters. Typically, the fans utilized in display adapters are frameless annular blade fans mounted on heat dissipation devices. However, components for frameless annular blade fans are somehow limited in the market, complicating the process for users seeking necessary parts during fan replacement, leading to annoyance in fan replacement for display adapters. Therefore, enhancing the ease of fan replacement for display adapters is a challenge that developers need to address.

### SUMMARY

Aspects of the disclosure provide an expansion card. The expansion card includes a first housing, a second housing coupled with the first housing to define an internal space, the second housing having at least one ventilation opening communicating with the internal space, a substrate disposed on the first housing and within the internal space, a heat dissipation device disposed on the substrate, and at least one fan disposed on the second housing and within the internal space, and located at the corresponding ventilation opening.

In an embodiment, the first housing can include a first side portion and at least one second side portion, the second side portion is connected to the first side portion, the substrate is disposed on the first side portion, the second housing includes a third side portion and at least one fourth side portion, the ventilation opening is disposed on the third side portion, the fourth side portion is connected to the third side portion, and the fourth side portion is disposed on the second side portion.

In an embodiment, the expansion card can further include at least one first fastening element, wherein the second side portion has at least one first fastening hole, the fourth side portion has at least one second fastening hole, and the first fastening element like no fastened to the first fastening hole and the second fastening hole to secure the fourth side portion to the second side portion.

In an embodiment, a number of the first fastening hole and a number of the second fastening hole are both plural, the plurality of first fastening holes are disposed in rows parallel to an extending direction of the first side portion, the plurality of second fastening holes are disposed parallel to an extending direction of the at least one second side portion, and the plurality of second fastening holes are aligned with the plurality of first fastening holes.

In an embodiment, a number of the second side portion and a number of the two dominant pixel fourth side portion are both two, the two second side portions are respectively connected to opposite sides of the first side portion, and the two fourth side portions are respectively connected to opposite sides of the third side portion. In some embodiments, the two second side portions are disposed between the two fourth side portions.

In an embodiment, the expansion card can further include at least one second fastening element, wherein the fan includes a fan frame and fan blades, the fan blades are rotatably disposed in the fan frame, and the fan frame is disposed on the third side portion of the second housing using the second fastening element.

In an embodiment, the first housing can include a first side portion and a second side portion, the second side portion is connected to the first side portion, the substrate is disposed on the first side portion, the second housing includes a third side portion and at least one fourth side portion, the ventilation opening is disposed on the third side portion, the fourth side portion is coupled with the third side portion, the first side portion is coupled with the fourth side portion, and the second side portion is coupled with the third side portion and the fourth side portion.

In an embodiment, the expansion card can further include a display chip, wherein the display chip is disposed on the substrate, and the heat dissipation device is thermally coupled to the display chip. In some embodiments, the heat dissipation device can include a vapor chamber, a plurality of heat pipes, and fins, the vapor chamber is thermally coupled to the display chip, a first end of each heat pipe is thermally coupled to the vapor chamber, and a second end of each heat pipe passes through the fins.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of an expansion card according to aspects of the present disclosure.

FIG. 2 illustrates another perspective view of the expansion card of FIG. 1.

FIG. 3 illustrates an exploded view of the expansion card of FIG. 1.

FIG. 4 illustrates another exploded view of the expansion card of FIG. 1.

FIG. 5 illustrates a cross-sectional view of the expansion card of FIG. 1.

FIG. 6 illustrates a perspective view of an expansion card according to aspects of the present disclosure.

FIG. 7 illustrates a cross-sectional view of the expansion card of FIG. 6.

FIG. 8 illustrates a perspective view of an expansion card according to aspects of the present disclosure.

FIG. 9 illustrates a cross-sectional view of the expansion card of FIG. 8.

FIG. 10 illustrates a perspective view of an expansion card according to aspects of the present disclosure.

FIG. 11 illustrates an exploded view of the expansion card of FIG. 10.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

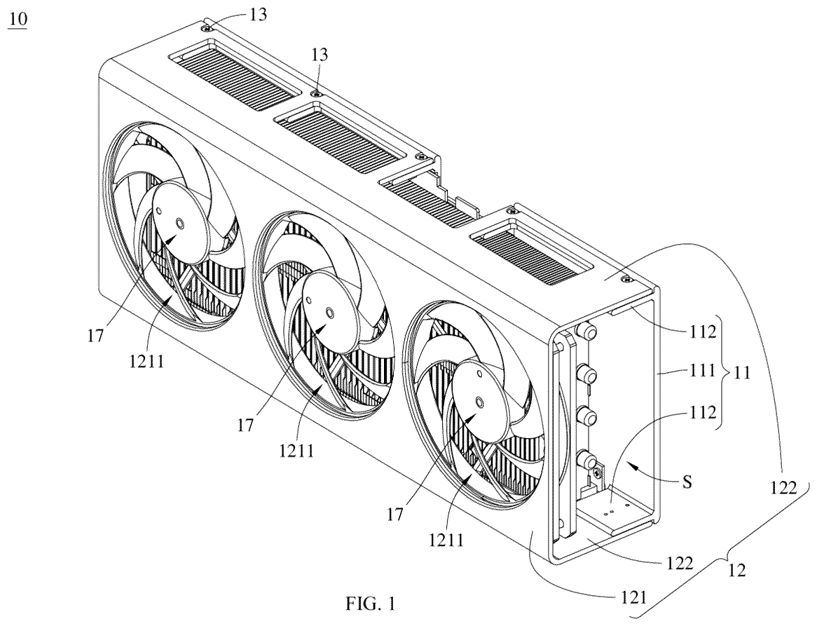

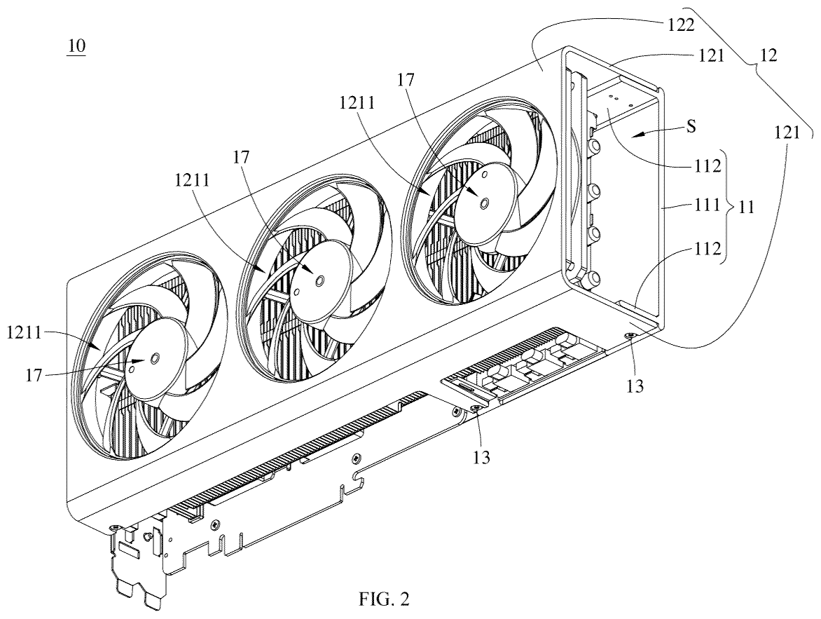

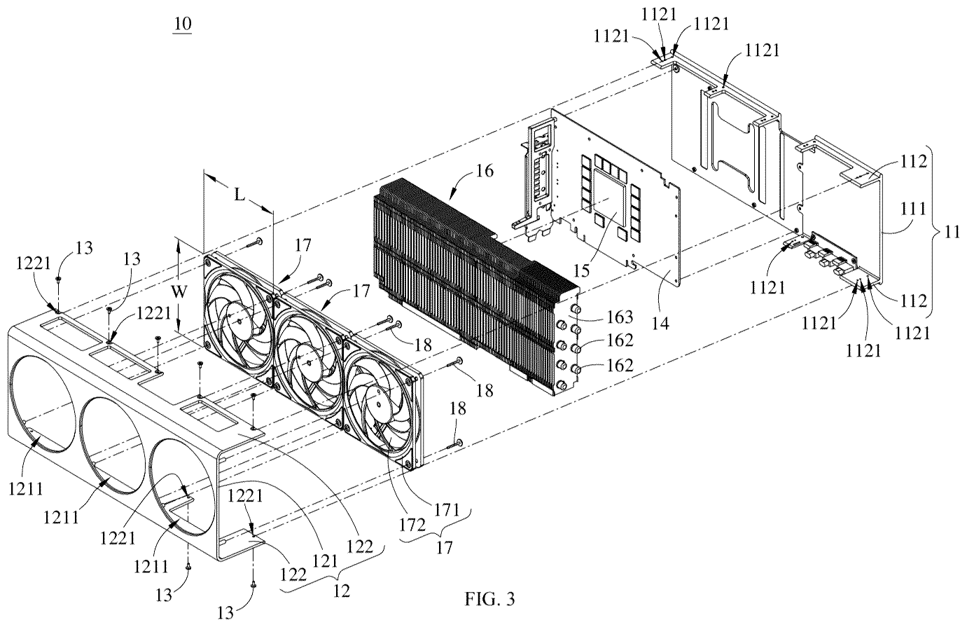

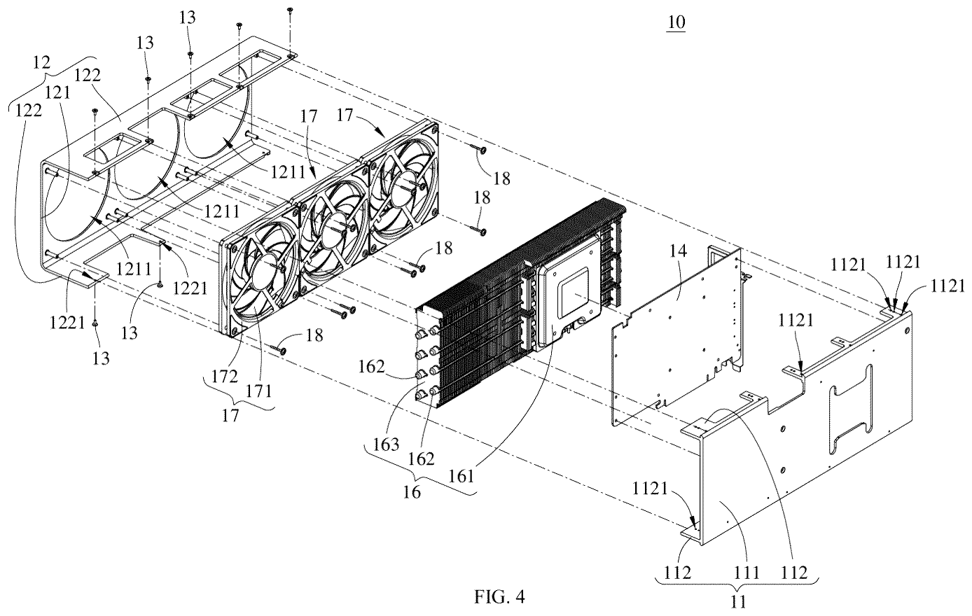

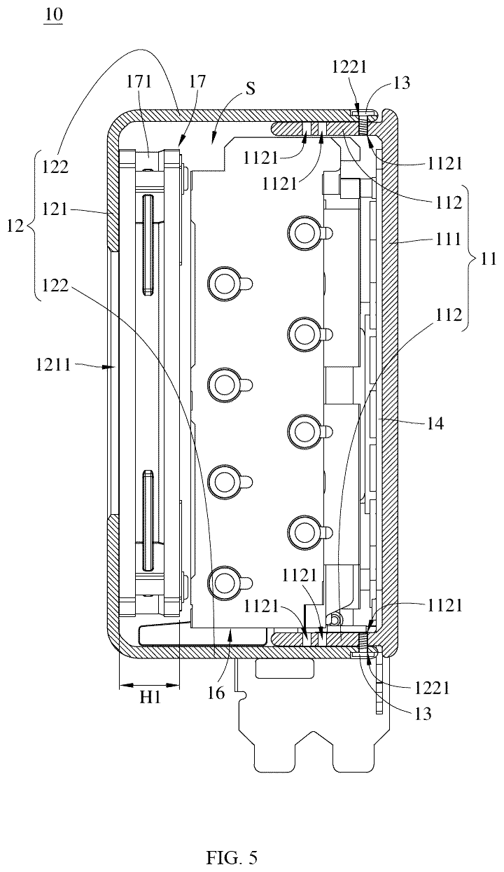

Please refer to FIGS. 1 to 5. FIG. 1 illustrates a perspective view of an expansion card 10 according to aspects of the present disclosure. FIG. 2 illustrates another perspective view of the expansion card 10 of FIG. 1. FIG. 3 illustrates an exploded view of the expansion card 10 of FIG. 1. FIG. 4 illustrates another exploded view of the expansion card of FIG. 1. FIG. 5 illustrates a cross-sectional view of the expansion card 10 of FIG. 1.

The expansion card 10 can include a first housing 11, a second housing 12, a plurality of first fastening elements 13, a substrate 14, a display chip 15, a heat dissipation device 16, a plurality of fans 17, and a plurality of second fastening elements 18. The second housing 12 is coupled with the first housing 11 to define an internal space S. The expansion card 10, for example, can be a graphic card or a display adapter.

The first housing 11 includes a first side portion 111 and two second side portions 112. The two second side portions 112 are respectively connected to opposite sides of the first side portion 111. Each second side portion 112 has a plurality of first fastening holes 1121. These first fastening holes 1121 are disposed in rows parallel to an extending direction of the first side portion 111. The second housing 12 includes a third side portion 121 and two fourth side portions 122. The two fourth side portions 122 are respectively connected to opposite sides of the third side portion 121. Each fourth side portion 122 has a plurality of second fastening holes 1221. These second fastening holes 1221 are disposed parallel to an extending direction of the second side portions 112.

The second fastening holes 1221 of the two fourth side portions 122 are aligned with the first fastening holes 1121 in the same row of the two second side portions 112. The first fastening elements 13 are fastened to the first fastening holes 1121 and the second fastening holes 1221, securing the two fourth side portions 122 to the two second side portions 112, respectively. The two second side portions 112 are disposed between the two fourth side portions 122. Furthermore, the first fastening elements 13 can be screws, while the first fastening holes 1121 and the second fastening holes 1221 can be designated as screw holes.

The substrate 14 is disposed on the first housing 11 and within the internal space S, specifically on the first side portion 111. The display chip 15 is disposed on the substrate 14. The heat dissipation device 16 is disposed on the substrate 16 and the display chip 15. The heat dissipation device 16 can include a vapor chamber 161, a plurality of heat pipes 162, and fins 163. The vapor chamber 161 is thermally coupled to the display chip 15. A first end of each heat pipe 162 is thermally coupled to the vapor chamber 161, while a second end of each heat pipe passes through the fins 163. The heat dissipation device 16 can absorb and dissipate heat generated by the display chip 15 during operation.

The fans 17 are disposed on the second housing 12 and within the internal space S. The third side portion 121 of the second housing 12 has a plurality of ventilation openings 1211. These ventilation openings 1211 communicate with the internal space S. The fans 17 are suitably positioned at the ventilation openings 1211. Each fan 17 includes a fan frame 171 and fan blades 172. The fan blades 172 are rotatably disposed in the fan frame 171. The fan frame 171 is secured to the third side portion 121 of the second housing 12 using the second fastening elements 18. The fans 17 generate cooling airflow, which flows into the internal space S through the ventilation openings 1211 to perform forced cooling on the heat dissipation device 16 that absorbs heat from the display chip 15. Screws can be used as the second fastening elements 18.

In one embodiment, length L and width W of the fan frame 171 can be 120 millimeters, and height H1 of the fan frame 171 can be 15 millimeters. The corresponding first fastening holes 1121 to the second fastening holes 1221 can be adjusted according to the dimensions of the fan frame 171, allowing the fourth side portion 122 to vary the position utilized to secure the second side portion 112 in accordance with the dimensions of the fan frame 171. For example, the second fastening holes 1221 in one embodiment can correspond to the first fastening holes 1121 situated on the outermost side.

In one embodiment, as the fans 17 are secured to the second housing 12 by screws, users can utilize commercially available general axial flow fans for replacement needs. This enhances the ease of fan replacement for the expansion card 10. Furthermore, the expansion card 10 can replace fans 17 of various sizes based on user requirements, increasing the fan replacement flexibility for the expansion card 10.

The number of second side portions 112 of the first housing 11 and the number of fourth side portions 122 of the second housing 12 are both two, but the present invention is not limited thereto. In other embodiments, the number of second side portions of the first housing and the number of fourth side portions of the second housing may both be only one.

In one embodiment, the numbers of first fastening holes 1121, second fastening holes 1221, and first fastening elements 13 are all plural, but the present invention is not limited thereto. In other embodiments, the numbers of first fastening holes, second fastening holes, and first fastening elements may all be only one.

In one embodiment, the numbers of fans 17, ventilation openings 1211, and second fastening elements 18 are all plural, but this is not limiting. In other embodiments, the numbers of fans, ventilation openings, and second fastening elements may all be only one.

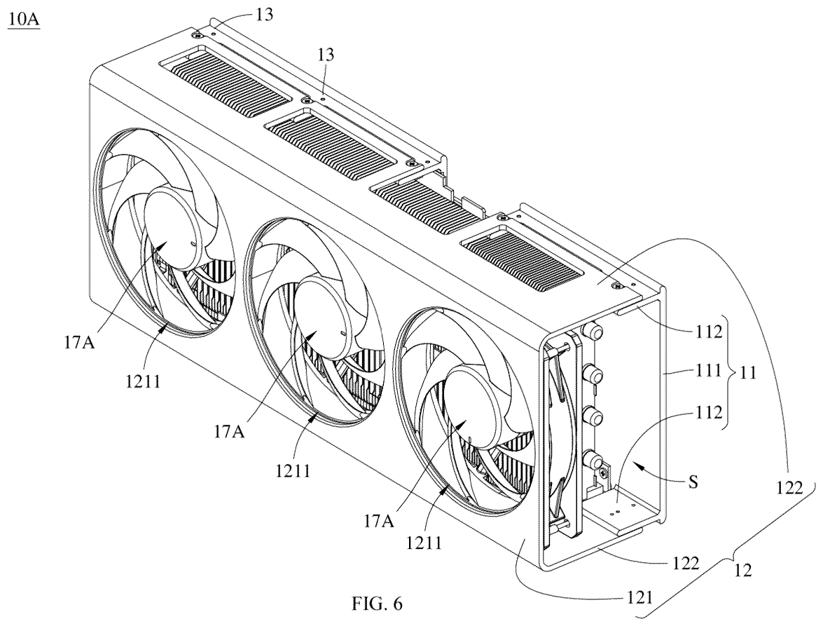

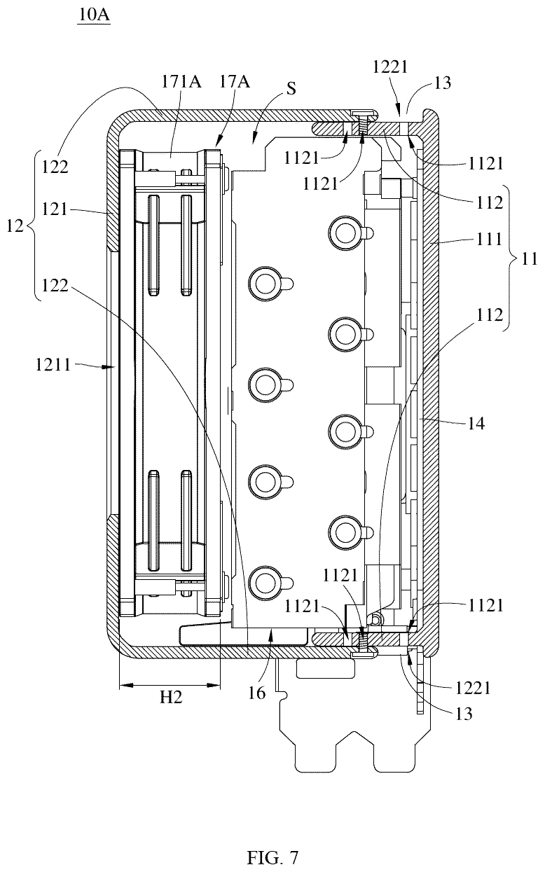

Please refer to FIGS. 6 and 7. FIG. 6 illustrates a perspective view of an expansion card 10A according to aspects of the present disclosure. FIG. 7 illustrates a cross-sectional view of the expansion card 10A of FIG. 6.

The expansion card 10A is similar to the expansion card 10. The length and width (not shown) of the fan frame 171A can be 120 millimeters, and the height H2 of the fan frame 171A can be 25 millimeters. The corresponding first fastening holes 1121 to the second fastening holes 1221 can be adjusted in accordance with the dimensions of the fan frame 171A. For example, the second fastening holes 1221 can correspond to the first fastening holes 1121 situated in the middle section.

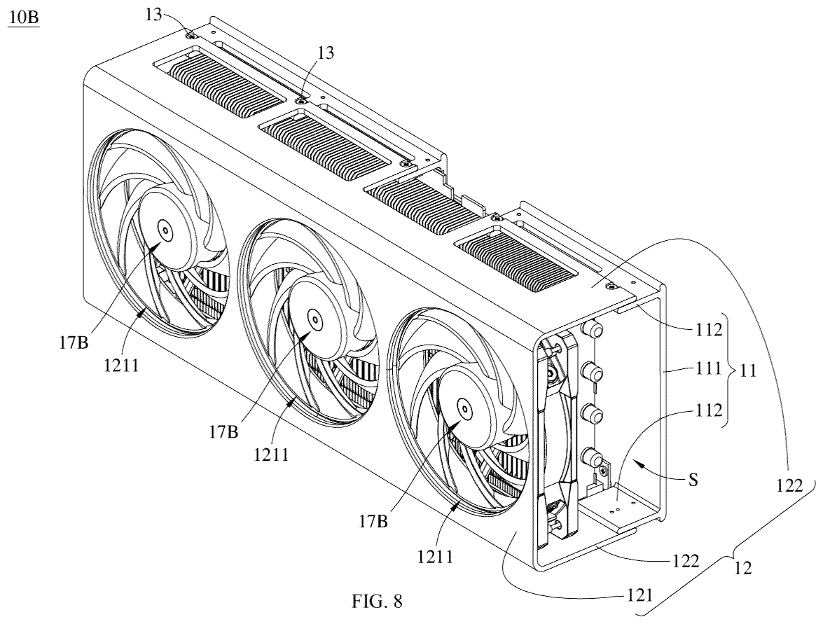

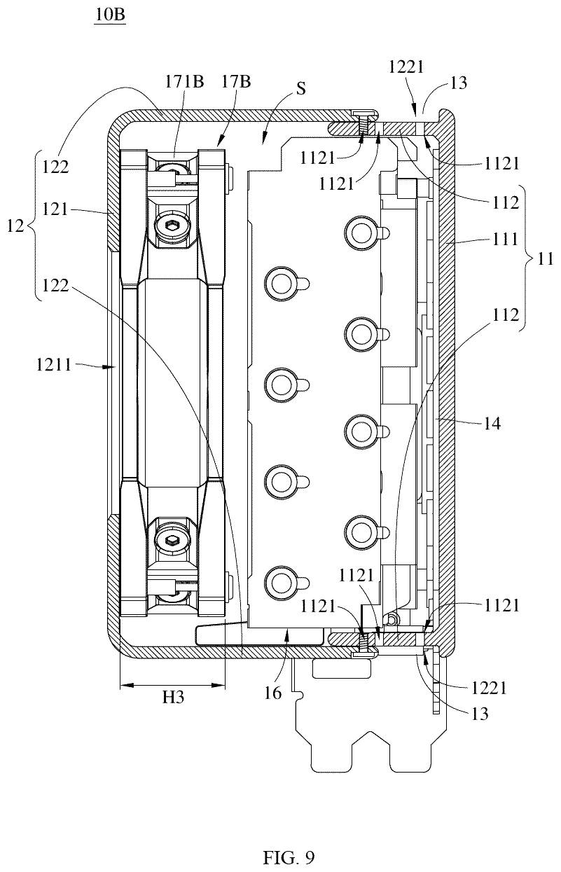

Please refer to FIGS. 8 and 9. FIG. 8 illustrates a perspective view of an expansion card 10B according to aspects of the present disclosure. FIG. 9 illustrates a cross-sectional view of the expansion card 10B of FIG. 8.

The expansion card 10B is similar to the expansion card 10. The length and width (not shown) of the fan frame 171B can be 120 millimeters, and the height H3 of the fan frame 171B can be 30 millimeters. The corresponding first fastening holes 1121 to the second fastening holes 1221 can be adjusted in accordance with the dimensions of the fan frame 171B. For example, the second fastening holes 1221 can correspond to the first fastening holes 1121 situated on the innermost side.

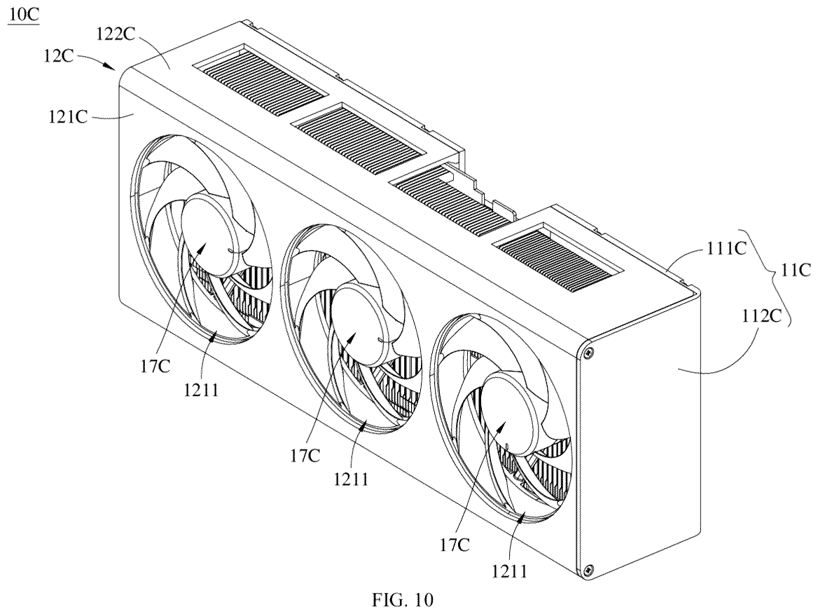

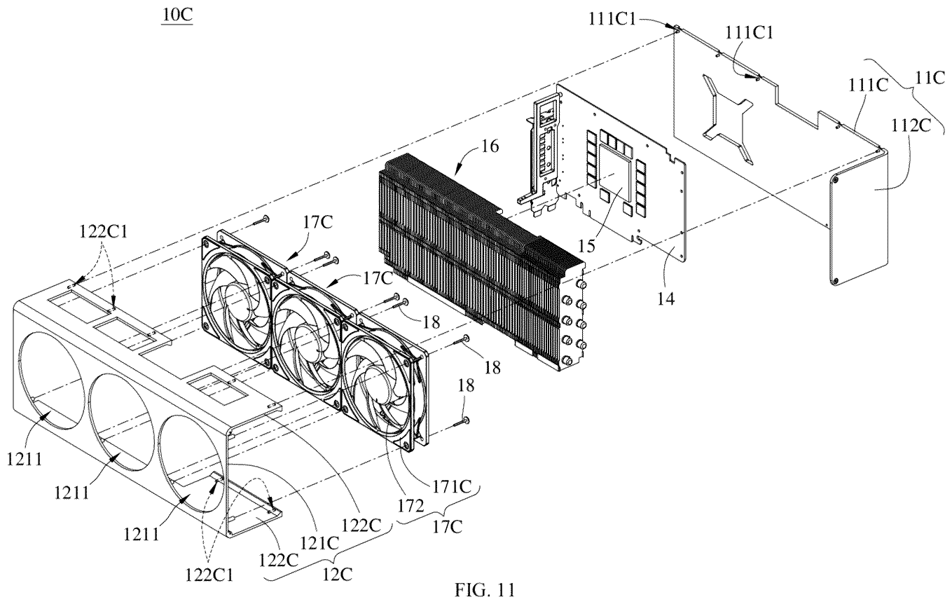

In the expansion cards 10, 10A, 10B, the side between the first side portion 111 and the third side portion 121 does not cover the internal space S, and the corresponding first fastening holes 1121 to the second fastening holes 1221 can be adjusted based on the dimensions of the fan frame 171, 171A, 171B. In other embodiments, this can be modified. Please refer to FIGS. 10 and 11. FIG. 10 illustrates a perspective view of an expansion card 10C according to aspects of the present disclosure. FIG. 11 illustrates an exploded view of the expansion card 10C of FIG. 10.

The expansion card 10C is similar to the expansion card 10. The first housing 11C includes a first side portion 111C and a second side portion 112C. The second side portion 112C is connected to the first side portion 111C. The second housing 12C includes a third side portion 121C and two fourth side portions 122C. The two fourth side portions 122C are respectively connected to opposite sides of the third side portion 121C. The first side portion 111C is coupled with the two fourth side portions 122C. The second side portion 112C is coupled with the third side portion 121C and the two fourth side portions 122C. That is, in the expansion card 10C, the first side portion 111C, and the second side portion 112C, the third side portion 121C, and the two fourth side portion 122C collectively form the internal space S.

Furthermore, the first side portion 111C have a plurality of first fastening holes 111C1. Each fourth side portion 122C has a plurality of second fastening holes 122C1. The first fastening holes 111C1 and the second fastening holes 122C1 are each arranged in a straight line without being divided into multiple rows. The first fastening holes 111C1 correspond to the second fastening holes 122C1 respectively. That is, the corresponding first fastening holes 1121 to the second fastening holes 1221 do not adjust according to the dimensions of the fan frame 171C, meaning the first housing 11C does not adjust the position secured to the second housing 12C according to the dimensions of the fan frame 171C.

In one embodiment, the number of fourth side portions 122C of the second housing 12C is two, but the current invention is not limited thereto. In other embodiments, the number of fourth side portions of the second housing may be only one.

According to the expansion cards of the previously mentioned embodiments, because the fans include fan frames and are disposed on the second housing, users can replace them with commercially available fans with frames. This simplifies the process of replacing fans for expansion cards. Furthermore, the expansion cards of the embodiments can replace fans of various sizes in accordance with user requirements, increasing the flexibility of fan replacement for expansion cards.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. An expansion card, comprising:
a first housing;
a second housing coupled with the first housing to define an internal space, the second housing having at least one ventilation opening communicating with the internal space;
a substrate disposed on the first housing and within the internal space;
a heat dissipation device disposed on the substrate; and
at least one fan disposed on the second housing and within the internal space, and located at the corresponding ventilation opening.

2. The expansion card of claim 1, wherein the first housing includes a first side portion and at least one second side portion, the second side portion is connected to the first side portion, the substrate is disposed on the first side portion, the second housing includes a third side portion and at least one fourth side portion, the ventilation opening is disposed on the third side portion, the fourth side portion is connected to the third side portion, and the fourth side portion is disposed on the second side portion.

3. The expansion card of claim 2, further comprising at least one first fastening element, wherein the second side portion has at least one first fastening hole, the fourth side portion has at least one second fastening hole, and the first fastening element is fastened to the first fastening hole and the second fastening hole to secure the fourth side portion to the second side portion.

4. The expansion card of claim 3, wherein a number of the first fastening hole and a number of the second fastening hole are both plural, the plurality of first fastening holes are disposed in rows parallel to an extending direction of the first side portion, the plurality of second fastening holes are disposed parallel to an extending direction of the at least one second side portion, and the plurality of second fastening holes are aligned with the plurality of first fastening holes.

5. The expansion card of claim 2, wherein a number of the second side portion and a number of the fourth side portion are both two, the two second side portions are respectively connected to opposite sides of the first side portion, and the two fourth side portions are respectively connected to opposite sides of the third side portion.

6. The expansion card of claim 5, wherein the two second side portions are disposed between the two fourth side portions.

7. The expansion card of claim 2, further comprising at least one second fastening element, wherein the fan includes a fan frame and fan blades, the fan blades are rotatably disposed in the fan frame, and the fan frame is disposed on the third side portion of the second housing using the second fastening element.

8. The expansion card of claim 1, wherein the first housing includes a first side portion and a second side portion, the second side portion is connected to the first side portion, the substrate is disposed on the first side portion, the second housing includes a third side portion and at least one fourth side portion, the ventilation opening is disposed on the third side portion, the fourth side portion is coupled with the third side portion, the first side portion is coupled with the fourth side portion, and the second side portion is coupled with the third side portion and the fourth side portion.

9. The expansion card of claim 1, further comprising a display chip, wherein the display chip is disposed on the substrate, and the heat dissipation device is thermally coupled to the display chip.

10. The expansion card of claim 9, wherein the heat dissipation device includes a vapor chamber, a plurality of heat pipes, and fins, the vapor chamber is thermally coupled to the display chip, a first end of each heat pipe is thermally coupled to the vapor chamber, and a second end of each heat pipe passes through the fins.
